(19) United States
(12) Patent Application Publication
(10) Pub. No.: US 2014/0182919 A1
(43) Pub. Date: Jul. 3, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventor: Ho Jin Kim, Suwon (KR)

(73) Assignee: SAMSUNG ELECTRO-MECHANICS CO., LTD., Suwon (KR)

(21) Appl. No.: 13/888,948

(22) Filed: May 7, 2013

(30) Foreign Application Priority Data
Dec. 31, 2012 (KR) 10-2012-0158649

(51) Int. Cl. H05K 1/02; H05K 3/00

(52) U.S. Cl. CPC H05K 1/0298; H05K 3/0011; H05K 3/0017
USPC 174/266; 427/97.2; 216/13

(57) ABSTRACT

Disclosed herein is a printed circuit board, including: a base substrate; a first insulating layer formed on the base substrate; a first via formed on the base substrate and formed to penetrate through the first insulating layer; a first plating layer formed to surround an upper part of the first insulating layer and a side and a lower part of the first via; a second via formed on at least one of the first via and the first insulating layer; and a second insulating layer formed on the first insulating layer and formed to surround a side of the second via.

### CROSS REFERENCE TO RELATED APPLICATION

This application claims the benefit of Korean Patent Application No. 10-2012-0158649, filed on Dec. 31, 2012, entitled “Printed Circuit Board And Method For Manufacturing The Same” which is hereby incorporated by reference in its entirety into this application.

### BACKGROUND OF THE INVENTION

1. Technical Field

The present invention relates to a printed circuit board and a method for manufacturing the same.

2. Description of the Related Art

In general, a printed circuit board is implemented by wiring a copper foil on one surface or both surfaces of a board made of various kinds of thermosetting synthetic resins, fixing IC or electronic components on the board, and implementing electrical wirings therebetween and then, coating the electrical wirings with an insulator. Recently, with the development of electronic industries, a demand for multi-functional and light and small electronic components has been rapidly increased. Accordingly, there is a need to increase a wiring density of a printed circuit board on which the electronic components are mounted and reduce a thickness thereof. Further, as electronic products are slimmed and light, a production of a printed circuit board using a build-up method implementing a junction between circuit layers as minimally as possible by connecting only the required circuit layers, not using a method of machining a plated through hole implemented in a multi-layer printed circuit board has been increased. As vias formed on the printed circuit board to which the build up method is applied, there are a staggered type via, an O-ring type via, a stack type via, and the like. Among those, the stack type via forming a via formed on the printed circuit board may be formed in order of forming a lower via on a lower insulating layer, a circuit pattern thereon, an upper insulating layer thereon, and an upper via thereon (U.S. Pat. No. 7,485,411). When the stack type via according to the related art is formed, the circuit pattern and the upper via are formed separately. Further, when the stack via is formed, a matching degree between the lower via and the upper via is low, and thus the defect may occur.

### SUMMARY OF THE INVENTION

The present invention has been made in an effort to provide a printed circuit board capable of reducing process time and a method for manufacturing the printed circuit board.

Further, the present invention has been made in an effort to provide a printed circuit board capable of improving a matching degree of a stack via and a method for manufacturing the printed circuit board.

According to a preferred embodiment of the present invention, there is provided a printed circuit board, including: a base substrate; a first insulating layer formed on the base substrate; a first via formed on the base substrate and formed to penetrate through the first insulating layer; a first plating layer formed to surround an upper part of the first insulating layer and a side and a lower part of the first via; a second via formed on at least one of the first via and the first insulating layer; and a second insulating layer formed on the first insulating layer and formed to surround a side of the second via.

The printed circuit board may further include: a second plating layer formed on at least one of the first plating layer and the first via.

The second via may be formed on the second plating layer that is formed on the first via.

The second via may be formed on the second plating layer that is formed on the first insulating layer.

The printed circuit board may further include a build up layer including: a third insulating layer formed on the second insulating layer; a circuit pattern formed on the second via and the second insulating layer; a third via formed on the circuit pattern and formed to penetrate through the third insulating layer; a third plating layer formed on the third insulating layer and formed to surround a side and a lower part of the third via; a fourth via formed on at least one of the third via and the third insulating layer; and a fourth insulating layer formed on the third insulating layer and formed to surround a side of the fourth via.

The printed circuit board may further include: a fourth plating layer formed on at least one of the third plating layer and the third via.

The fourth via may be formed on the fourth plating layer that is formed on the third via.

The fourth via may be formed on the fourth plating layer that is formed on the third insulating layer.

According to another preferred embodiment of the present invention, there is provided a method for manufacturing a printed circuit board, including: providing a base substrate; forming a first insulating layer including a first via hole on the base substrate; forming a first plating layer on the first insulating layer and an inner wall of the first via hole; forming a first via by filling the first via hole; forming a second via on at least one of the first via and the first plating layer; and forming a second insulating layer on the first insulating layer.

The base substrate may further include a circuit pattern formed thereon.

The forming of the first insulating layer may include: forming a first insulating layer on the base substrate; and forming the first via hole penetrating through the first insulating layer.

The forming of the first plating layer may include: forming a first plating layer by an Electroless plating method on the first insulating layer and an inner wall of the first via hole; forming an etching resist on the first plating layer so that a part of the first plating layer is exposed; etching the first plating layer exposed by the etching resist; and removing the etching resist.

The etching resist may be formed on the first via.

The method for manufacturing a printed circuit board may further include: after the forming of the first via, forming a second plating layer on the first via.

The method for manufacturing a printed circuit board may further include: after the forming of the first via, forming the second plating layer on the first plating layer.

In the forming of the second via, the second via may be formed on the second plating layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a printed circuit board according to a preferred embodiment of the present invention;

FIGS. 2 to 10 are exemplified diagrams illustrating a method for manufacturing a printed circuit board according to a preferred embodiment of the present invention; and

FIG. 11 is an exemplified diagram illustrating a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

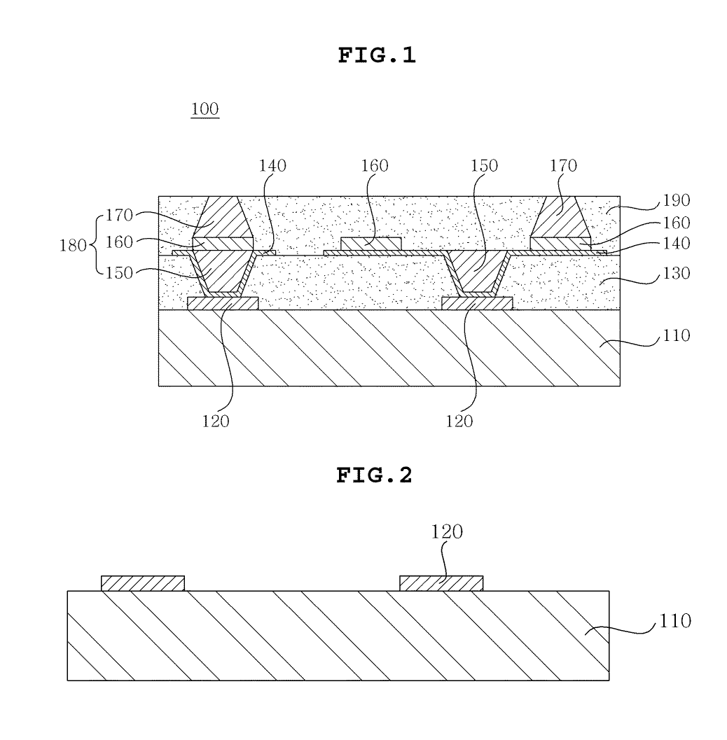

FIG. 1 is an exemplified diagram illustrating a printed circuit board according to a preferred embodiment of the present invention.

Referring to FIG. 1, a printed circuit board 100 may include a base substrate 110, a first insulating layer 130, a first via 150, a first plating layer 140, a second plating layer 160, a second via 170, and a second insulating layer 190.

The base substrate 110 may generally be formed of composite polymer resin used as an interlayer insulating material. For example, the base substrate 110 may adopt prepreg to manufacture the printed circuit board thinner. Alternatively, an ajinomoto build up film (ABF) may be adopted as the base substrate 110 to easily implement a fine circuit. In addition to this, the base substrate 110 may be formed of epoxy-based resin such as FR-4, bismaleimide trianzine (BT), and the like, but the preferred embodiment of the present invention is not particularly limited thereto. Further, as the base substrate 110, a copper clad laminate (CCL) may be used.

A first circuit pattern 120 may be formed on the base substrate 110. The first circuit pattern 120 may be formed to transmit an electrical signal. The first circuit pattern 120 formed of an electrically conductive material may be formed on the base substrate 110. For example, the electrically conductive material may be copper. Further, the base substrate 110 is not illustrated, but may be formed with a through via (not illustrated) through which upper and lower parts of the base substrate 100 may be electrically connected with each other.

The first insulating layer 130 may be formed on the base substrate 110. The first insulating layer 130 may be formed of phenol resin, epoxy resin, imide resin, and the like. In addition, the first insulating layer 130 may be formed of prepreg including a reinforcing material.

The first via 150 may be formed on the first circuit pattern 120. Further, the first via 150 may have a form penetrating through the first insulating layer 130.

The first plating layer 140 may be formed on the first insulating layer 130. Further, the first plating layer 140 may be formed to surround a side and a lower part of the first via 150. That is, the first plating layer 140 may be formed so as to extend from an upper part of the first insulating layer 130 and connect with the side and lower part of the first via 150.

The second plating layer 160 may be formed on the first via 150. Further, the second plating layer 160 may be formed on the first plating layer 140. The second plating layer 160 may serve as a lead-in wire of the second via 170. Alternatively, when the second via 170 is not formed on the second plating layer 160, the second plating layer may serve as the first circuit pattern.

The second via 170 may be formed on the second plating layer 160. In addition, the second via 170 may have a form penetrating through the second insulating layer 190. According to the preferred embodiment of the present invention, a stack via 180 formed with the second via 170 may be formed on the first via 150.

The second insulating layer 190 may be formed on the first insulating layer 130. Further, the second insulating layer 190 may be formed to surround the second via 170. The second plating layer 160 on which the second via 170 is not formed may be buried into the upper part of the second insulating layer 190.

The preferred embodiment of the present invention describes that one stack via 180 is formed on the printed circuit board 100, but is not limited thereto. That is, one or more build up layer may be formed on the printed circuit board 100 to form the plurality of stack vias 180.

Method for Manufacturing Printed Circuit Board

FIGS. 2 to 10 are exemplified diagrams illustrating a method for manufacturing a printed circuit board according to a preferred embodiment of the present invention.

Referring to FIG. 2, the base substrate 110 may be first provided. The base substrate 110 may generally be formed of composite polymer resin used as an interlayer insulating material. For example, the base substrate 110 may adopt prepreg to manufacture the printed circuit board thinner. Alternatively, an ajinomoto build up film (ABF) may be adopted as the base substrate 110 to easily implement a fine circuit. In addition to this, the base substrate 110 may be formed of epoxy-based resin such as FR-4, bismaleimide trianzine (BT), and the like, but the preferred embodiment of the present invention is not particularly limited thereto. Further, as the base substrate 110, a copper clad laminate (CCL) may be used.

A first circuit pattern 120 may be formed on the base substrate 110. The first circuit pattern 120 may be formed to transmit an electrical signal. The first circuit pattern 120 formed of an electrically conductive material may be formed on the base substrate 110. For example, the electrically conductive material may be copper. Further, the base substrate 110 is not illustrated, but may be formed with a through via (not illustrated) through which upper and lower portions of the base substrate 110 may be electrically connected with each other. The first circuit pattern 120 and the through via (not illustrated) may be formed by applying a known technology.

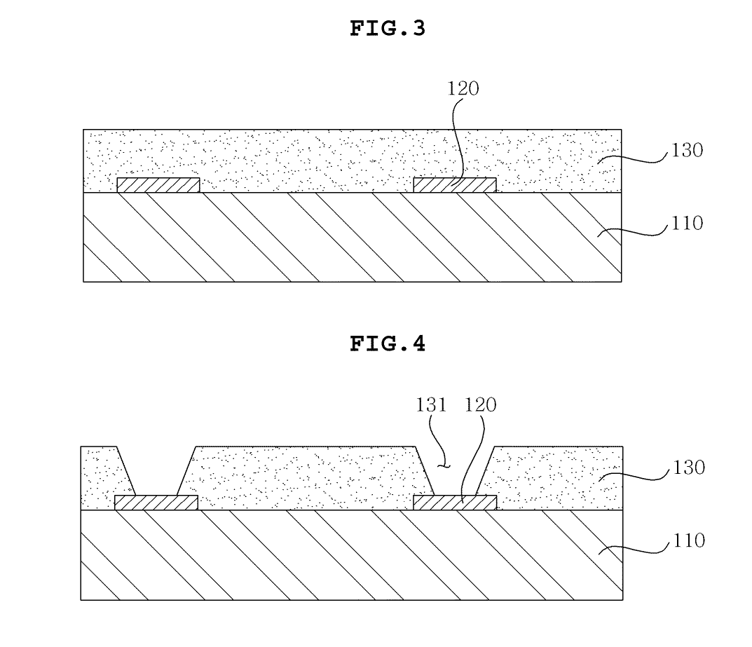

Referring to FIG. 3, the first insulating layer 130 may be formed on the base substrate 110. The first insulating layer 130 may be formed of phenol resin, epoxy resin, imide resin, and the like. In addition, the first insulating layer 130 may be formed of prepreg including a reinforcing material.

Referring to FIG. 4, a first via hole 131 may be formed on the first insulating layer 130. The first via hole 131 may be formed to penetrate through the first insulating layer 130. That is, the first via hole 131 may expose the first circuit pattern 120 formed on the base substrate 110. The first via hole 131 may be formed by etching the first insulating layer 130 using a laser. However, the method for forming the first via hole 131 is not limited thereto. The first via hole 131 may be formed by using a laser or a CNC drill or plasma. Alternatively, the first via hole 131 may be formed by performing exposure and development on the first insulating layer 130. According to the preferred embodiment of the present invention, when the first via hole 131 is formed using a laser, as illustrated in FIG. 3, the first via hole 131 may have a taper shape.

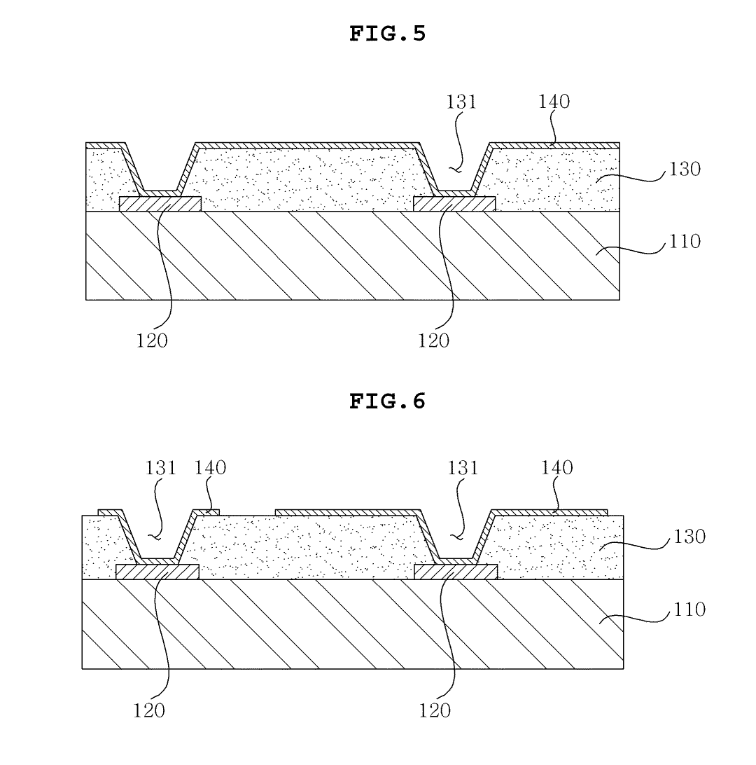

Referring to FIG. 5, the first plating layer 140 may be formed. The first plating layer 140 may be formed on the first insulating layer 130 and an inner wall of the first via hole 131. The first plating layer 140 may be formed of electrically conductive metal. For example, the first plating layer 140 may be formed of copper. Further, the first plating layer 140 may be formed by an electroless plating method.

Referring to FIG. 6, the first plating layer 140 may be patterned. The first plating layer 140 may be patterned so as to insulate between the first via 150 and the second plating layers 160 that are formed later. First, an etching resist (not illustrated) may be formed on the first plating layer 140. The etching resist (not illustrated) may be formed to open an area in which the first plating layer 140 is removed. The etching resist (not illustrated) may be formed on the first plating layer 140 and etched. In this case, the method for etching the first plating layer 140 is not particularly limited, and therefore may be performed by a method known to the art. For example, the first plating layer 140 may be etched by a quick etching method or a flash etching method. After the etching is performed, the first plating layer 140 may be patterned by removing the etching resist (not illustrated).

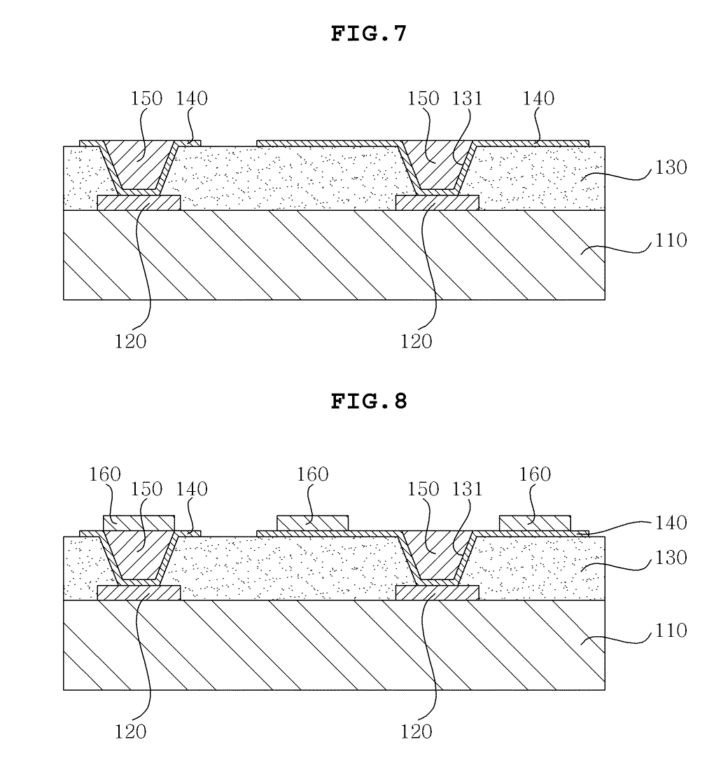

Referring to FIG. 7, the first via 150 may be formed. The first via 150 may be formed by filling the first via hole 131. The first via 150 may be formed of an electrically conductive material. The first via 150 may be formed by an electroplating method using the first plating layer 140 formed in the inner wall of the first via hole 131 as a lead-in wire.

Referring to FIG. 8, the second plating layer 160 may be formed. The second plating layer 160 may be formed on at least one of the first via 150 and the first plating layer 140. First, a plating resist (not illustrated) of which the area formed with the second plating layer 160 is opened may be formed on the first insulating layer 130. The second plating layer 160 may be formed by filling the opened area of the plating resist (not illustrated). The second plating layer 160 may be formed using at least one of the electroless plating method or the electroplating method. The second plating layer 160 is formed, and then the plating resist (not illustrated) may be removed. According to the preferred embodiment of the present invention, as illustrated in FIG. 8, the second plating layer 160 may be formed on the first via 150 and the first plating layer 140, respectively.

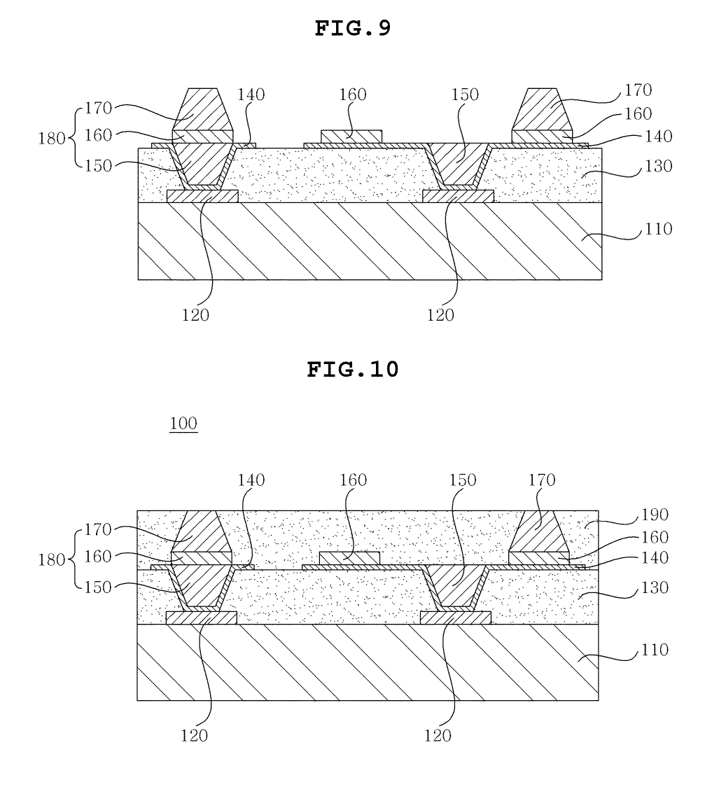

Referring to FIG. 9, the second via 170 may be formed. The second via 170 may be formed on the second plating layer 160. According to the preferred embodiment of the present invention, the second via 170 may be formed on the second plating layer 160 that is formed on the first via 150. Further, the second via 170 may be formed on the second plating layer 160 that is formed on the first insulating layer 130. However, the second via 170 is not necessarily formed on all the second plating layers 160. When the second plating layer 160 serves as the first circuit pattern, the second via 170 may not be formed on the second plating layer 160. A position at which the second via 170 is not formed may be changed by a design of a person skilled in the art to which the present invention pertains. As such, the stack via 180 may be formed by forming the second via 170 on the first via 150. According to the preferred embodiment of the present invention, the second plating layer 160 may also be a first circuit pattern and may be a part of the stack via 180. That is, the first circuit pattern and a part of the stack via 180 may be simultaneously formed by the process of forming the second plating layer 160.

Referring to FIG. 10, the second insulating layer 190 may be formed. The second insulating layer 190 may be formed on the first insulating layer 130. The second insulating layer 190 may be formed so as to bury the first plating layer 140 and the second plating layer 160. Further, the second insulating layer 190 may be formed to surround a side of the second via 170. The second insulating layer 190 may be formed of the same material as the first insulating layer 130.

The preferred embodiment of the present invention describes that one stack via 180 having a double layer structure is formed on the printed circuit board 100, but is not limited thereto. By repeatedly performing the process of FIGS. 2 to 9, the printed circuit board 100 having a structure in which a plurality of stack vias 180 are stacked.

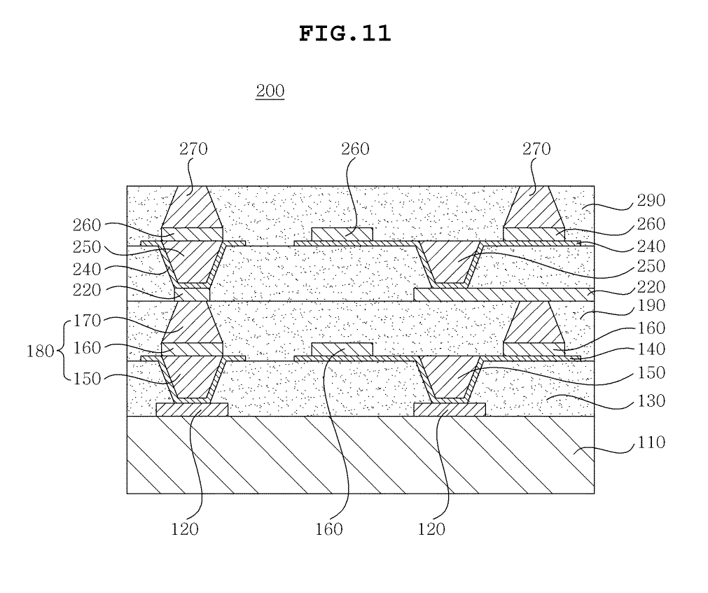

FIG. 11 is an exemplified diagram illustrating a printed circuit board according to another preferred embodiment of the present invention.

Referring to FIG. 11, a printed circuit board 200 may include the base substrate 110, the first circuit pattern 120, the first insulating layer 130, the first via 150, the first plating layer 140, the second plating layer 160, the second via 170, the second insulating layer 190, a second circuit pattern 220, a third insulating layer 230, a third via 250, a third plating layer 240, a fourth plating layer 260, a fourth via 270, and a fourth insulating layer 290.

The base substrate 110 may generally be formed of composite polymer resin used as an interlayer insulating material. For example, the base substrate 110 may adopt prepreg to manufacture the printed circuit board thinner. Alternatively, an ajinomoto build up film (ABF) may be adopted as the base substrate 110 to easily implement a fine circuit. In addition to this, the base substrate 110 may be formed of epoxy-based resin such as FR-4, bismaleimide trianzine (BT), and the like, but the preferred embodiment of the present invention is not particularly limited thereto. Further, as the base substrate 110, a copper clad laminate (CCL) may be used.

The first circuit pattern 120 may be formed on the base substrate 110. The first circuit pattern 120 may be formed to transmit an electrical signal. The first circuit pattern 120 formed of an electrically conductive material may be formed on the base substrate 110. For example, the electrically conductive material may be copper. Further, the base substrate 110 is not illustrated, but may be formed with a through via (not illustrated) through which upper and lower portions of the base substrate 110 may be electrically connected with each other.

The first insulating layer 130 may be formed on the base substrate 110. The first insulating layer 130 may be formed of phenol resin, epoxy resin, imide resin, and the like. In addition, the first insulating layer 130 may be formed of prepreg including a reinforcing material.

The first via 150 may be formed on the first circuit pattern 120. Further, the first via 150 may have a form penetrating through the first insulating layer 130.

The first plating layer 140 may be formed on the first insulating layer 130. Further, the first plating layer 140 may be formed to surround a side and a lower part of the first via 150. That is, the first plating layer 140 may be formed so as to extend from an upper part of the first insulating layer 130 and connect with the side and lower part of the first via 150.

The second plating layer 160 may be formed on the first via 150. Further, the second plating layer 160 may be formed on the first plating layer 140. The second plating layer 160 may serve as a lead-in wire of the second via 170. Alternatively, when the second via 170 is not formed on the second plating layer 160, the second plating layer may serve as the circuit pattern.

The second via 170 may be formed on the second plating layer 160. In addition, the second via 170 may have a form penetrating through the second insulating layer 190. According to the preferred embodiment of the present invention, the stack via 180 formed with the second via 170 may be formed on the first via 150.

The second insulating layer 190 may be formed on the first insulating layer 130. Further, the second insulating layer 190 may be formed to surround the second via 170. The second plating layer 160 on which the second via 170 is not formed may be buried into the upper part of the second insulating layer 190.

The second circuit pattern 220 may be formed on the second insulating layer 190. The second circuit pattern 220 may be formed for the electrically conductive material. For example, the electrically conductive material may be copper.

The third insulating layer 230 may be formed on the second insulating layer 190. The third insulating layer 230 may be formed of phenol resin, epoxy resin, imide resin, and the like. In addition, the third insulating layer 230 may be formed of prepreg including a reinforcing material.

The third via 250 may be formed on the second circuit pattern 220. In addition, the third via 250 may have a form penetrating through the third insulating layer 230.

The third plating layer 240 may be formed on the third insulating layer 230. Further, the third plating layer 240 may be formed to surround a side and a lower part of the third via 250. That is, the third plating layer 240 may be formed so as to extend from an upper part of the third insulating layer 230 and connect with the side and lower part of the third via 250.

The fourth plating layer 260 may be formed on the third via 250. Further, the fourth plating layer 260 may be formed on the third plating layer 240. The fourth plating layer 260 may serve as a lead-in wire of the fourth via 270. Alternatively, when the fourth via 270 is not formed on the fourth plating layer 260, the fourth plating layer may serve as the circuit pattern.

The fourth via 270 may be formed on the fourth plating layer 260. In addition, the fourth via 270 may have a form penetrating through the fourth insulating layer 290.

The fourth insulating layer 290 may be formed on the third insulating layer 230. Further, the fourth insulating layer 290 may be formed to surround the fourth via 270. The fourth plating layer 260 on which the fourth via 270 is not formed may be buried into the upper part of the fourth insulating layer 290.

By repeating the structure of the insulating layer, the via, and the plating layer, the printed circuit board on which the build up layer including the plurality of stack vias is formed may be formed.

According to the printed circuit board and the method for manufacturing a printed circuit board according to the preferred embodiments of the present invention, the process time may be reduced by the plating layer. In the related art, the circuit pattern and the stack via are manufactured by a separate process. However, according to the preferred embodiments of the present invention, the circuit pattern and a part of the stack via are simultaneously formed by the same process due to the formation of the plating layer, thereby reducing the process time.

In addition, to the printed circuit board and the method for manufacturing a printed circuit board according to the preferred embodiments of the present invention, the via is formed and then the insulating layer is formed, thereby improving the matching degree between the vias or between the plating layer and the via.

According to the preferred embodiments of the present invention, the printed circuit board and the method for manufacturing a printed circuit board can simultaneously form the circuit pattern and a part of the stack via by the same process, thereby reducing the process time.

According to the preferred embodiments of the present invention, the printed circuit board and the method for manufacturing a printed circuit board can form the via and form the insulating layer, thereby improving the matching degree of the stack via.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims

What is claimed is:

1. A printed circuit board, comprising:
a base substrate;
a first insulating layer formed on the base substrate;
a first via formed on the base substrate and formed to penetrate through the first insulating layer;
a first plating layer formed to surround an upper part of the first insulating layer and a side and a lower part of the first via;
a second via formed on at least one of the first via and the first insulating layer; and
a second insulating layer formed on the first insulating layer and formed to surround a side of the second via.

2. The printed circuit board as set forth in claim 1, further comprising:
a second plating layer formed on at least one of the first plating layer and the first via.

3. The printed circuit board as set forth in claim 2, wherein the second via is formed on the second plating layer that is formed on the first via.

4. The printed circuit board as set forth in claim 2, wherein the second via is formed on the second plating layer that is formed on the first insulating layer.

5. The printed circuit board as set forth in claim 1, further comprising:
a build up layer including:
a third insulating layer formed on the second insulating layer;
a circuit pattern formed on the second via and the second insulating layer;
a third via formed on the circuit pattern and formed to penetrate through the third insulating layer;
a third plating layer formed on the third insulating layer and formed to surround a side and a lower part of the third via;
a fourth via formed on at least one of the third via and the third insulating layer; and
a fourth insulating layer formed on the third insulating layer and formed to surround a side of the fourth via.

6. The printed circuit board as set forth in claim 5, further comprising:
a fourth plating layer formed on at least one of the third plating layer and the third via.

7. The printed circuit board as set forth in claim 6, wherein the fourth via is formed on the fourth plating layer that is formed on the third via.

8. The printed circuit board as set forth in claim 6, wherein the fourth via is formed on the fourth plating layer that is formed on the third insulating layer.

9. A method for manufacturing a printed circuit board, comprising:
providing a base substrate;
forming a first insulating layer including a first via hole on the base substrate;
forming a first plating layer on the first insulating layer and an inner wall of the first via hole;
forming a first via by filling the first via hole;
forming a second via on at least one of the first via and the first plating layer; and
forming a second insulating layer on the first insulating layer.

10. The method as set forth in claim 9, wherein the base substrate further includes a circuit pattern formed thereon.

11. The method as set forth in claim 9, wherein the forming of the first insulating layer includes:
forming a first insulating layer on the base substrate; and
forming the first via hole penetrating through the first insulating layer.

12. The method as set forth in claim 9, wherein the forming of the first plating layer includes:
forming a first plating layer by an Electroless plating method on the first insulating layer and an inner wall of the first via hole;
forming an etching resist on the first plating layer so that a part of the first plating layer is exposed;
etching the first plating layer exposed by the etching resist; and
removing the etching resist.

13. The method as set forth in claim 12, wherein the etching resist is formed on the first via.

14. The method as set forth in claim 9, further comprising: after the forming of the first via, forming a second plating layer on the first via.

15. The method as set forth in claim 14, further comprising: after the forming of the first via, forming the second plating layer on the first plating layer.

16. The method as set forth in claim 15, wherein in the forming of the second via, the second via is formed on the second plating layer.
